(19) United States
(12) Patent Application Publication
(10) Pub. No.: US 2017/0373019 A1
(43) Pub. Date: Dec. 28, 2017

(54) METHOD TO MITIGATE CHIP PACKAGE INTERACTION RISK ON DIE CORNER USING REINFORCING TILES

(71) Applicant: GLOBALFOUNDRIES Inc., Grand Cayman (KY)

(72) Inventor: Mohamed RABIE, Clifton Park, NY (US)

(21) Appl. No.: 15/193,700

(22) Filed: Jun. 27, 2016

(51) Int. Cl. H01L 23/00; H01L 23/498

(52) U.S. Cl. CPC H01L 23/562; H01L 24/05; H01L 24/13; H01L 23/49811; H01L 23/49838; H01L 2224/0401

(57) ABSTRACT

A method for producing semiconductor devices including reinforcing metal tiles and the resulting semiconductor package are provided. Embodiments include forming one or more reinforcing metal tiles at corners of an upper portion of a metal stack of semiconductor die during manufacturing of the semiconductor die; and attaching the semiconductor die to a packaging substrate.

### TECHNICAL FIELD

The present disclosure relates to semiconductor device fabrication. In particular, the present disclosure relates to integrated circuit (IC) packaging in advanced technology nodes.

### BACKGROUND

Integrated circuit packaging is the final stage of semiconductor device fabrication in which the silicon die is encased in a supporting case or package that prevents physical damage and corrosion. The case or package should be able to withstand high temperatures. A reliability test is conducted on the package in which the temperature is cycled, for example, about 1000, 1250 or even 2000 times between negative 55° C. and 125° C. Mechanical stresses are created in the package due to the mismatch between the coefficients of thermal expansions (CTE) of various materials existing in the package. Those mechanical stresses can result in cracks or delamination between different layers existing in the back-end-of-line (BEOL) layers. The main mechanical stress risk imposed due to chip package interaction (CPI) risk is under the bumps which attach the die to the substrate, as well as at the corner of the die. Flip chip packaging has been causing failures to the BEOL structure near the corner of the flip chip due to the stresses imposed by the substrate to die CTE mismatch. In addition, stress on the die increases in presence of the lid due to the restriction on the die and substrate movement imposed by the lid and the CTE mismatch between the lid and both the die and the substrate. The underfill material attaches the substrate to the die. The higher the elasticity modulus of the underfill, the better the attachment between the substrate and the die, but higher the stress imposed on the corner. Corner stress is dominated by shear stress while under the bump stress is dominated by peeling stress.

CPI reliability risk has been traditionally mitigated by calibrating the packaging parameters to decrease the stresses caused by packaging. Those parameters include modifying underfill material, adjusting the pattern of the bumps in the underlying structure, adjusting core thickness of the package substrate, and adjusting the thickness and material of the covering lid. However, these proposed solutions do not address the root cause of the problem and corner failures still result.

A need exists for methodology enabling manufacture of a more robust semiconductor structure to further mitigate the CPI risk of the die and the resulting device.

### SUMMARY

An aspect of the present disclosure is a method of reducing the CPI risk imposed on the corner of the die due to CTE mismatch by including reinforcing metal tiles in the BEOL layers near the corner of the die and making the BEOL structure more robust. Finite element method (FEM) simulations demonstrate that if reinforcing metal tiles are added to the structure, such that the reinforcing metal tiles are on top of the metal stack, CPI stress in the dielectric under the tiles is reduced by 25% compared to the neighboring high risk dielectric regions.

From experimental experience and simulations, it was determined that there is a strong correlation between the failure and the stress/strain gradient. Areas with highest stress/strain gradient fail before areas with highest stress/strain. Strain gradient enhances the plasticity of the metal. The areas with highest strain gradient are affected with multiple temperature cycles as the metal enters the plastic regime multiple times. The metal tiles eliminate the in-plane stress/strain gradient and solves the failure problem with temperature cycle.

A further aspect of the present disclosure is a device including semiconductor die and reinforcing metal tiles in the back end of line (BEOL) layers near the corner of the die.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming reinforcing metal tiles at corners of an upper portion of a metal stack of semiconductor die during manufacturing of the semiconductor die; and attaching the semiconductor die to a packaging substrate.

Aspects of the present disclosure include attaching the semiconductor die to the packaging substrate with solder bumps, balls and/or copper pillars. Other aspects include the semiconductor die being a flip chip. Additional aspects include forming the reinforcing metal tiles at corners of far back end of line (FBEOL) metal layers of the metal stack. Other aspects include forming the reinforcing metal tiles at the corners of the semiconductor die with a metal deposition process. Yet other aspects include forming the reinforcing metal tiles at the corners of the semiconductor die. In certain aspects, each corner is defined by a rectangle such that two edges of the corner are on edges of the semiconductor die adjacent the underfill material and the remaining two edges are tangents to the outermost solder bumps or balls. Further aspects include the solder bumps or balls and/or copper pillars being in contact with metal lines in the semiconductor die. Other aspects include forming reinforcing metal tiles with a metal selected from aluminum (Al), copper (Cu), titanium (Ti), tungsten (W) or tantalum (Ta). Yet other aspects include forming reinforcing metal tiles at corners of upper portions of a plurality of metal stacks of semiconductor die during manufacturing of the semiconductor die. Further aspects include the metal stacks including Cu.

Another aspect of the present disclosure is a device including reinforcing metal tiles formed at corners of an upper portion of a metal stack of semiconductor die; and a packaging substrate to which the semiconductor die is attached by solder balls, bumps and/or copper pillars.

Aspects include the semiconductor die being a flip chip. Other aspects include the reinforcing metal tiles being formed at corners of FBEOL metal layers of the metal stack. Certain aspects include the reinforcing metal tiles being formed at the corners of the semiconductor die, and each corner being defined by a rectangle such that two edges of the corner are on edges of the semiconductor die adjacent the underfill material and the remaining two edges are tangents to the outermost solder bumps or balls. Other aspects include the solder bumps, balls and/or copper pillars being in contact with a top metal layer through under bump metallization (UBM) in the FBEOL. Additional aspects include the reinforcing metal tiles including a metal selected from Al, Cu, Ti, W or Ta. Other aspects include a plurality of metal stacks of the semiconductor die, each metal stack having reinforcing metal tiles formed at corners.

In yet another aspect of the present disclosure, there is provided a method including forming one or more reinforcing metal tiles at corners of an upper portion of a metal stack of semiconductor die during manufacturing of the semiconductor die; and attaching the semiconductor die to a packaging substrate with solder bumps, balls and/or copper pillars, wherein: the one or more reinforcing metal tiles are formed at the corners of the semiconductor, and each corner is defined by a rectangle such that two edges of the corner are on edges of the semiconductor die adjacent the underfill material and the remaining two edges are tangents to the outermost solder bumps or balls.

Aspects include the solder bumps, balls and/or copper pillars being in contact with a top metal layer through UBM in the FBEOL.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a layout of a quarter of a semiconductor package including a lid, semiconductor die and packaging substrate;

FIG. 2 is a magnified view of region B of FIG. 1 showing a corner region where one or more reinforcing metal tiles are positioned, in accordance with an exemplary embodiment;

FIGS. 3A-3F is a top views of a metal stack(s) having a reinforcing metal tile, in accordance with an exemplary embodiment; and

FIG. 4 is a cross-sectional view of a metal stack with vias, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of cracks and delamination occurring between BEOL layers due to packaging and operation of a semiconductor die. In accordance with embodiments of the present disclosure, reinforcing metal tiles are included at corners of the die to reduce the CPI risk of the die by making the semiconductor structure more robust.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

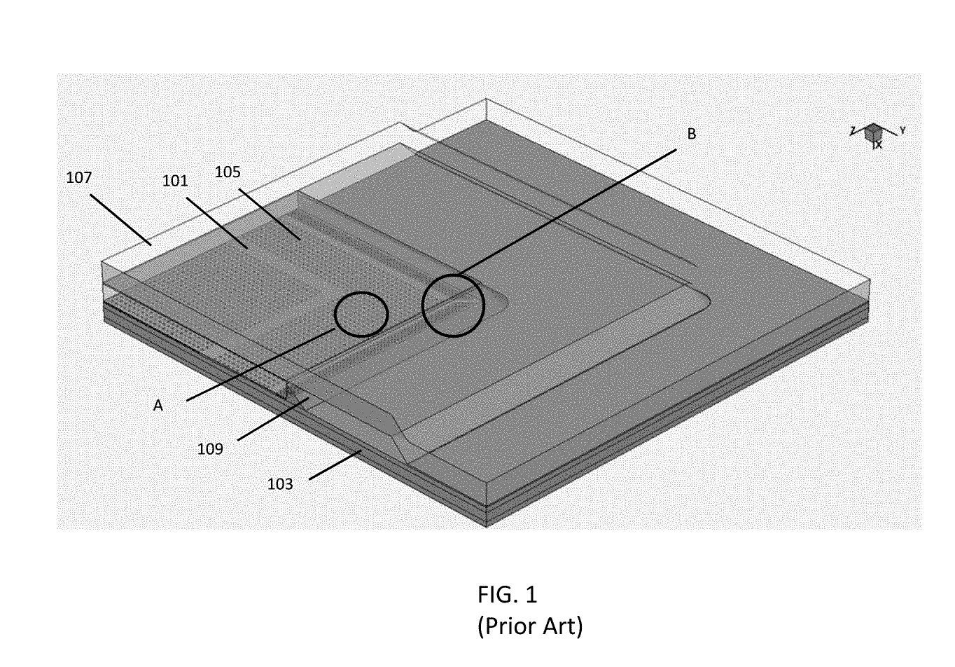

Adverting to FIG. 1, an example of a semiconductor package is illustrated. A semiconductor die 101, such as an IC die, is mounted to a packaging substrate 103 by solder bumps, balls, and/or copper pillars 105 which are deposited onto pads of the semiconductor die 101. For flip chip packaging, during final wafer processing, the UBM is deposited on metal pads, for example aluminum pads, and the copper pillars/bumps are formed on top of the UBM. In order to mount the semiconductor die 101 to external circuitry (e.g., a circuit board or another semiconductor chip or die), it is flipped over so that its top side faces down, and aligned so that its pads align with matching pads on the external circuit, and then the solder is reflowed to complete the interconnect. A metal lid 107 forms the top outer surface of the semiconductor packaging and can be made of copper. An underfill material 109 is formed around the edges of the semiconductor die and surround the bumps in gaps between the die and the package where no bumps exits. The underfill material 109 functions to reinforce and protect the bumps from mechanical failure, corrosion, etc. The underfill material 109 reinforces the bumps. The underfill material 109 is in direct contact with the bumps and/or copper pillars.

The main mechanical stress risk imposed due to CPI risk is under the bumps and/or copper pillars 105 which attach the semiconductor die to 101 to the packaging substrate 103, as indicated by circled region A. Further, mechanical stress risk due to CPI risk also exists at the corner of the semiconductor die 101, as indicated by circled region B.

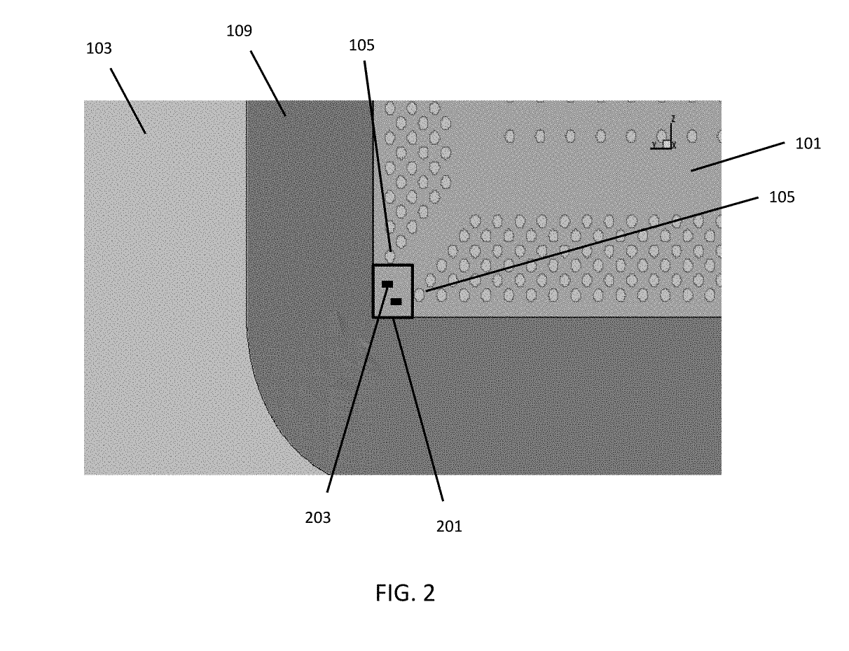

Adverting to FIG. 2, a magnified portion of circled region B according to the present disclosure is shown. A corner region 201 of the semiconductor die 101 is the location at which one or more metal reinforcing tiles 203 are positioned. The corner is defined by a rectangle such that two edges of the reinforcing metal tile(s) 203 are on the edges of the semiconductor die 101 and the other two edges are tangents to the outermost corner bumps 105. In certain embodiments, the corner regions 201 can be covered by a single metal reinforcing tile 203.

The reinforcing metal tiles 203 are formed at the corners of the semiconductor die 101 with a metal deposition process, including sputtering, or any other physical vapor deposition technique. The reinforcing metal tiles are formed to a thickness of 300 to 10000 nm. The shape of the reinforcing metal tiles 203 is square or rectangular with side dimensions of 1 to 500 μm. The reinforcing metal tiles are composed of Al, Cu, Ti, W or Ta. No additional masks are needed to form the reinforcing metal tiles 101 and only a modification in the design rules is needed. The same metal used to build the metal reinforcing tiles 203 is used to create a contact between the solder bumps/copper pillars and the top metal layer in the BEOL stack. The metal reinforcing tiles 203 are vertically positioned between the underfill material 109 and the top layer in the BEOL stack. The layer where the metal reinforcing tiles 203 exist is commonly referred to as the far back end of line layer (FBEOL). FEM simulations demonstrate that regions underneath the reinforcing metal tile 201 have a maximum stress that is about 25% less compared to regions outside of the reinforcing metal tile 201 and that the stress gradient is reduced from values above 100 MPa/um to less than 10 MPa/um. When reinforcing metal tile(s) 203 are added, such that the reinforcing metal tiles 203 are on top of the metal stack, CPI stress in the dielectric under the tiles is reduced by 25% compared to the neighboring high risk dielectric regions.

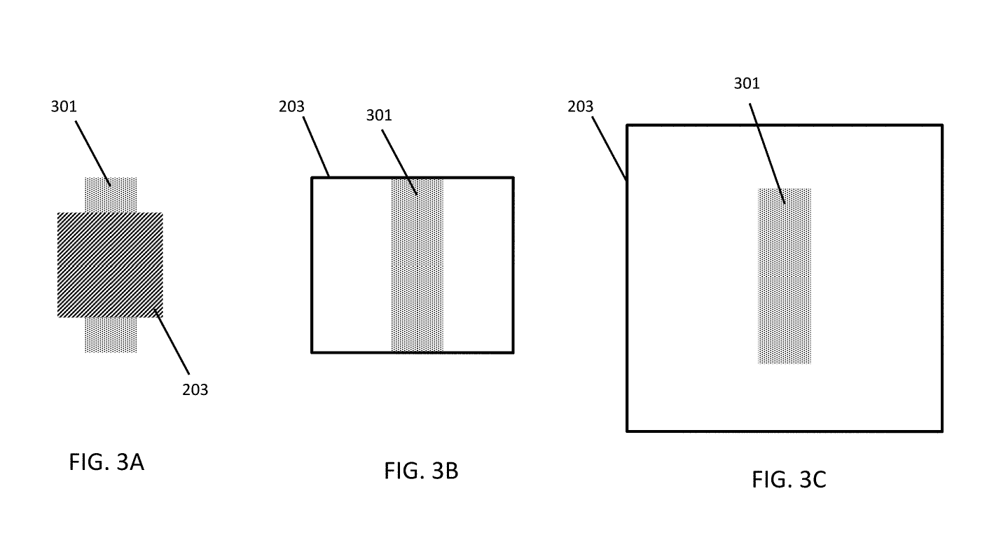

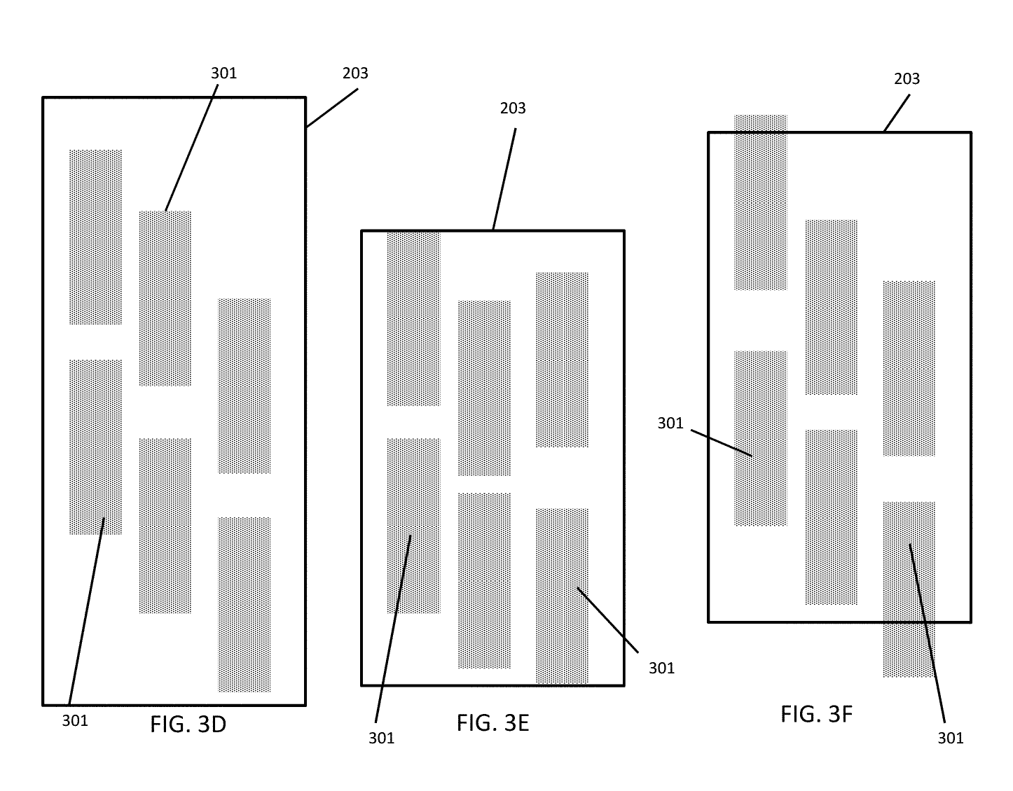

Adverting to FIGS. 3A-3C, the reinforcing metal tile(s) 203 is formed on top of metal stack 301 to minimize the stress/strain and strain gradient in the stack to avoid failure. The metal stack 301 is not in contact with the metal tile 203, but separated by a dielectric. The vertical spacing can be 1 to 30 μm, the risk of failure is reduced because the reinforcing metal tile 201 reduces the stress as well as the stress gradients. The reinforcing metal tiles 201 are required to be on the top of the metal stack 301 to minimize the strain gradient in the metal stack 301 to avoid failure. For each metal stack 301, reinforcing metal tiles 201 are formed on the top of the metal stacks at each corner. Thus, in this example, a single metal reinforcing tile 203 is provided for each metal stack 301. In alternative embodiment, as shown in FIGS. 3D-3F, a single metal reinforcing tile 203 is provided for multiple metal stacks 301. FIGS. 3A-3F show that the tiles can completely cover the metals or be tangent to them or intersect with the edge metals with the preference of the tiles completely covering the metals with a margin (e.g., FIGS. 3C and 3D) given that this configuration results in the lowest stress and stress gradient. In yet other embodiments, an entire corner can be covered with a metal tile.

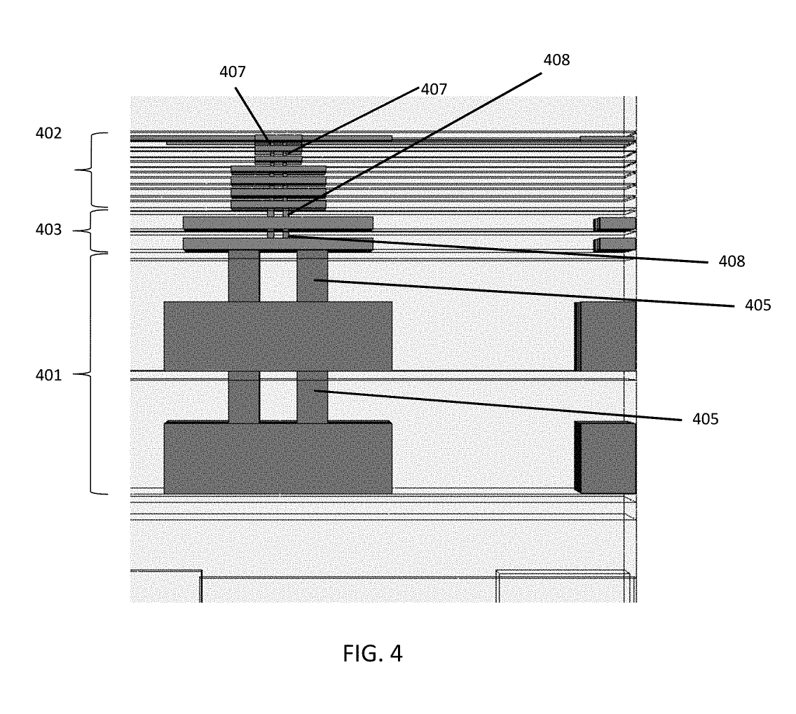

With reference to FIG. 4, an explanation of the von Mises stress gradient in the vias of a metal stack is explained. The dielectric materials used in layers 402 have lower dielectric constant and lower elasticity modulus than the dielectric materials used in layers 401. The drastic change in the properties of the dielectric materials results in a strain gradient. The highest gradient is in layers 403 which are considered to be transition layers between 401 and 402. Metal vias 407 are the narrowest vias and they have the highest stress. However, the highest stress gradient is in the vias 408 in layer 403. This stress gradient enhances the plasticity of the vias 408 and consequently results in mechanical failure with temperature cycling which, in turn, causes electrical failure. With the addition of reinforcing metal tiles added to the top of the metal stack (which corresponds to the bottom of FIG. 4 since the drawing is displayed upside down given the that it is a flip-chip representation), the von Mises stress gradient can be reduced in the transition layer 402 of the metal stack.

The embodiments of the present disclosure can achieve several technical effects, including eliminating the risk of corner failure due to CPI risk with no additional masks and with modification of only the design rules. The present disclosure is particularly beneficial to application-specific integrated circuit (ASIC) applications and 7 nm packaging with large dies and higher CPI corner risk expected. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of semiconductor packages.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming one or more reinforcing metal tiles directly on and at corners of an upper portion of a metal stack of a semiconductor die during manufacturing of the semiconductor die; and
attaching the semiconductor die to a packaging substrate,
wherein each corner is defined by a rectangle such that two edges of the corner are on edges of the semiconductor die adjacent to underfill material and the remaining two edges are tangents to outermost solder bumps or balls.

2. The method according to claim 1, comprising:
attaching the semiconductor die to the packaging substrate with solder bumps, balls and/or copper pillars.

3. The method according to claim 2, wherein the semiconductor die is a flip chip

4. The method according to claim 1, comprising:
forming the one or more reinforcing metal tiles at corners of far back end of line (FBEOL) metal layers of the metal stack.

5. (canceled)

6. The method according to claim 5, comprising:
forming the one or more reinforcing metal tiles at the corners of the semiconductor die with a metal deposition process.

7. (canceled)

8. The method according to claim 1, wherein the solder bumps, balls, and/or copper pillars are in contact with metallization in the semiconductor die.

9. The method according to claim 1, comprising forming reinforcing metal tiles with a metal selected from aluminum (Al), copper (Cu), titanium (Ti), tungsten (W) or tantalum (Ta).

10. The method according to claim 1, comprising:
forming reinforcing metal tiles at corners of upper portions of a plurality of metal stacks of semiconductor die during manufacturing of the semiconductor die.

11. The method according to claim 9, wherein the metal stacks comprise Cu.

12. A device comprising:
one or more reinforcing metal tiles formed directly on and at corners of an upper portion of a metal stack of a semiconductor die; and
a packaging substrate to which the semiconductor die is attached by solder balls or bumps,
wherein each corner is defined by a rectangle such that two edges of the corner are on edges of the semiconductor die adjacent to underfill material and the remaining two edges are tangents to outermost solder bumps or balls.

13. The device according to claim 12, wherein the semiconductor die is a flip chip.

14. The device according to claim 12, wherein the reinforcing metal tiles are formed at corners of far back end of line (FBEOL) metal layers of the metal stack.

15. (canceled)

16. The device according to claim 12, wherein the solder bumps, balls and/or copper pillars are in contact with metallization in the semiconductor die.

17. The device according to claim 12, wherein the reinforcing metal tiles comprise a metal selected from aluminum (Al), copper (Cu), titanium (Ti), tungsten (W) or tantalum (Ta).

18. The device according to claim 12, further comprising:
a plurality of metal stacks of the semiconductor die, each metal stack having reinforcing metal tiles formed at corners.

19. A method comprising:
forming one or more reinforcing metal tiles directly on and at corners of an upper portion of a metal stack of a semiconductor die during manufacturing of the semiconductor die; and
attaching the semiconductor die to a packaging substrate with solder bumps, balls and/or copper pillars, wherein:
the reinforcing metal tiles are formed at the corners of the semiconductor die, and
each corner is defined by a rectangle such that two edges of the corner are on edges of the semiconductor die adjacent to underfill material and the remaining two edges are tangents to outermost solder bumps or balls.

20. The method according to claim 19, wherein the solder bumps, balls and/or copper pillars are in contact with a top metal layer through metallization in the FBEOL metal layers of the metal stack.
